(19) United States
(12) Patent Application Publication
(10) Pub. No.: US 2024/0324152 A1
(43) Pub. Date: Sep. 26, 2024

(54) Cooling Apparatus

(71) Applicant: YASA LIMITED, Kidlington, Oxfordshire (GB)

(72) Inventors: Simon David Hart, Welshpool (GB); Tim Woolmer, Waterperry (GB); Michael David Pantrey, Banbury (GB); Rajesh Kudikala, Thatcham (GB); Daniel Rendell, Abingdon (GB); Paul Donald Spendley, Banbury (GB); Timothy James Leopold Farmer, Woodcote (GB); Adam Robert Neal, Welwyn Garden City (GB); Antony John Webster, Montgomery (GB)

(21) Appl. No.: 18/578,862

(22) PCT Filed: Jul. 15, 2022
(86) PCT No.: PCT/EP2022/069949

§ 371 Date: Jan. 12, 2024

(30) Foreign Application Priority Data
Jul. 15, 2021 (GB) 2110176.1

(51) Int. Cl. H05K 7/20; H02M 7/00

(52) U.S. Cl. CPC H05K 7/20927; H02M 7/003; H05K 7/20254; H05K 7/20272; H05K 7/209

(57) ABSTRACT

We describe a power converter cooling arrangement in which a base has a top plate of a thermally conductive material, and a bottom plate and side walls define a chamber. An inlet and outlet are in fluid communication with the chamber, and the chamber is flooded with a cooling fluid that flows between the inlet and outlet. A PCB of a power converter is mounted to, and thermally coupled with, the top plate, where the PCB receives a plurality of power modules (that are used in the power conversion). The base comprises a plurality of fluid channels for flowing cooling fluid therethrough. Each of the fluid channels is arranged to coincide with a location of one or more components mounted to the PCB.

### FIELD OF THE INVENTION

The present invention relates to a cooling apparatus, in particular a cooling apparatus for a power converter, and a cooling apparatus for cooling power devices. Such arrangements are useful, but are not limited to, cooling of power devices used in power conversion, for example power inverters.

### BACKGROUND OF THE INVENTION

Increasing power demand in smaller power units has been a long-standing technology driver in many fields and in this last decade has taken on new urgency in the development of power inverters for electric machines. For many applications the push for more power in a smaller space i.e., increase in power density is to reduce carrying of unnecessary weight that wastes energy, and for many applications, particularly for passenger vehicles, space is a premium commodity.

Numerous inventions have tackled the challenge of optimising power density, often focussing on ways to remove heat from particular components, usually the weakest link being active power switches e.g., IGBTs.

There has now come a stage in power converter (for example inverters) development where cooling of IGBT's though still critically important, is on a par with several other components and attention to cooling of active switches now needs to be done in parallel with new critical components, particularly capacitors used for energy storage and levelling.

So called DC link capacitors minimise the effects of voltage variations as loads change and provide a low impedance path for ripple currents generated by switching circuits. DC link capacitors are now on a par with active switch devices in their relevance for inverter reliability. Though much has been done to improve, maximum temperature ratings, fault tolerance and over voltage capacities, all key specification parameters for both IGBTs and DC Link capacitors, overall device reliability improves where effort is given to reducing and controlling their operation temperatures.

General Motors US2008117602 addresses cooling of a power inverter using power modules having pin fin heat sinks bolted to a cooling structure housing an array of DC link capacitors. Gate Drivers are not included and are assumed as separate, thereby reducing power density.

Hyundai U.S. Pat. No. 10,414,286 takes a similar route to address active switch and DC link capacitor cooling, and includes gate driver and control boards. Whereas heat is extracted from capacitor and power modules into liquid cooled channels, there is considerable further advantage to be had in reducing complexity and improving heat removal.

Gate drivers and control circuit components are also not immune from the drive to increased power density and whole system approaches are now required for reliability.

Whilst there has clearly been work to manage the operating conditions of DC link capacitors alongside active switches in inverter modules, demand for cheaper, lighter, smaller continues and we have seen a need to further address heat removal from active switches and DC link capacitors alongside managing heat distribution and removal from the whole system whilst minimising additional components and connections.

We have therefore appreciated the need for improved cooling apparatus for cooling power converters and power devices.

### SUMMARY OF THE INVENTION

The present invention provides a power converter cooling arrangement and a power module cooling arrangement according to the independent claims appended hereto. Further advantageous embodiments are provided in accordance with the dependent claims, also appended hereto.

In particular, we describe a power converter cooling arrangement, the power converter for converting an input voltage into an output voltage, the power converter comprising: an input for receiving an input voltage, and an output for outputting an output voltage; a plurality of power modules connected between the input and output, each module comprising a plurality of power devices mounted on and thermally coupled to a front face of a heatsink, the power module for converting the input voltage into an output voltage; a plurality of capacitors connected to the input; wherein the plurality of power modules and the plurality of capacitors are mounted to a PCB, the cooling arrangement comprising: a base having a top plate of a thermally conductive material, a bottom plate and side walls defining a chamber, and an inlet and outlet in fluid communication with the chamber, the chamber being flooded with a cooling fluid that flows between the inlet and outlet, wherein the PCB is mounted to, and thermal coupled with, an outer surface of the top plate of the base, and wherein the base comprises a plurality of fluid channels for flowing cooling fluid therethrough, each of the fluid channels being arranged to coincide with a location of one or more components mounted to the PCB.

Advantageously, this arrangement enables a contained fluid common circuit to be provided that offers component cooling without the components coming into contact with the cooling fluid. As such, a range of dirty and aggressive oils may be used without the issues of touching the electric components or PCBs.

One or more of the fluid channels may comprise one or more portions having a greater width than other portions of the fluid channels. One or more cooling features may protrude from an inner surface of the top plate into the one or more wider portions of the fluid channels and in contact with the cooling fluid. The one or more cooling features comprise fins.

One or more of the capacitors and/or one or more heatsinks and/or one or more features of one or more of the power devices are located to coincide with one or more of the fluid channels of the base.

The PCB may comprise one or more areas of copper located to coincide with the location of one or more of the fluid channels of the base.

The heatsink of each of the plurality of power modules may be mounted to a thermal module, the thermal module having an inlet for receiving cooling fluid, and an outlet for expelling cooling fluid and a chamber flooded with cooling fluid, the inlet and outlet of the thermal module being in fluid communication with the chamber of the base. The thermal module inlet and outlet may extend through the PCB into the base. The thermal module may comprises a polymer material.

A rear face of the heatsink may be exposed to the chamber of the thermal module so as to be in contact with the cooling fluid in the chamber of the thermal module, the rear face of the heatsink being opposed the front face of the heatsink.

The heatsink rear face may comprise one or more heat exchange elements arranged to contact the cooling fluid in the thermal module chamber. The one or more heat exchange elements may comprise pins or fins projecting from the rear face of the heatsink into the thermal module chamber.

The cooling arrangement may comprise a flow diverter in the flow path of the cooling fluid between the inlet and outlet of the thermal module, the flow diverter being arranged to cause the cooling fluid to meander through the thermal module chamber. The flow diverter may comprise: a top plate arranged substantially parallel to the rear face of the heatsink, the top plate having an inner face facing towards the rear face of the heatsink and an outer face opposing the inner face, the top plate having a length extending between the inlet and outlet of the thermal module; a plurality of inner baffles for blocking flow of the cooling fluid, the inner baffles extending from the inner face of the top plate towards the rear face of the heatsink; a plurality of outer baffles for blocking flow of the cooling fluid, the outer baffles extending from the outer face of the top plate to an inner wall of the thermal module; and a plurality of through-slots in the top plate configured to allow the cooling fluid to flow between the inner and outer surfaces of the top plate, wherein inner baffles and outer baffles are arranged alternately along the length of the top plate.

The plurality of through-slots may comprise a first plurality of through-slots located in the top plate between inner and outer baffles, and a second plurality of through-slots located in the top plate between outer and inner baffles. The first plurality of through-slots may be arranged between the inner and outer baffles to enable flow of the cooling fluid towards the heatsink through the top plate, and the second plurality of through-slots may be arranged between the outer and inner baffles to enable flow of the cooling fluid from the outer face of the top plate towards the heatsink, and wherein the first and second plurality of through-slots are arranged along the length of the top plate of the flow diverter so as to allow the cooling fluid to meander through the thermal module chamber alternately away from the heatsink through the second plurality of through-slots and towards the heatsink through the first plurality of through-slots.

Each of the first plurality of through-slots may comprise a plurality of rows of parallel slots. Each of the second plurality of through-slots may comprise a single through-slot arranged perpendicular to the first plurality of through-slots and extending over a portion of a height of the top plate.

The height of one or more of the inner and/or outer baffles may be less than the height of the top plate so as to permit at least a portion of the cooling fluid to flow over the top or underneath the respective inner or outer baffle. This provides a bleed path for incoming cooler cooling fluid into areas of the heatsink that would be hotter.

The plurality of power modules may be arranged in a plurality of pairs of modules. For each pair of power modules, the respective pair of thermal modules may be arranged substantially parallel to one another and separated by a gap. In some embodiments, they may be arranged parallel to each other without being separated by a gap.

In embodiments comprising thermal modules having a gap therebetween, the one or more of the capacitors may located within the gap between the respective pair of thermal modules. The respective pair of thermal modules may be thermally coupled to the respective one or more capacitors.

The respective pair of thermal modules may be supported and joined together at each end using respective support structures, and wherein the respective pair of thermal modules and respective support structures may surround the one or more capacitors.

For one or more of the power modules, a respective heatsink may be configured as a busbar for transferring power between the respective one or more of the plurality of power devices mounted thereto.

The power converter may further comprise one or more busbars for transferring power, the busbars being mounted to the PCB.

The power converter may comprise three of the plurality of power modules, each power module being configured to output a respective output voltage. The three power modules may be arranged substantially parallel to one another along a length of the PCB. Each of the power modules may receive the input voltage at a first end of the power module, and outputs a respective output voltage at a second end of the respective power module.

The power converter may further comprise a control PCB for controlling one or more of the components and/or for interfacing with external devices, and wherein the control PCB may be located above the plurality of power modules.

The cooling arrangement may comprise a housing extending from the base to enclose the power converter.

The power converter may be configured as an inverter for converting a DC input into an AC output.

We also describe a power module cooling arrangement, the power module for converting an input voltage into an output voltage, comprising: a plurality of power devices mounted on and thermally coupled to a front face of a heatsink; a thermal module having an inlet for receiving cooling fluid, and an outlet for expelling cooling fluid and a chamber flooded with cooling fluid, wherein the heatsink is mounted to the thermal module and a rear face of the heatsink is exposed to the chamber of the thermal module so as to be in contact with the cooling fluid in the chamber of the thermal module, the rear face of the heatsink being opposed the front face of the heatsink; and a flow diverter in the flow path of the cooling fluid between the inlet and outlet of the thermal module, wherein the flow diverter is arranged to cause the cooling fluid to meander through the thermal module chamber. The thermal module may comprises a polymer material.

Advantageously, this arrangement enables a contained fluid common circuit to be provided that offers component cooling without the components coming into contact with the cooling fluid. As such, a range of dirty and aggressive oils may be used without the issues of touching the electric components or PCBs. When electrical isolation is present between the heatsink and the components such as the power devices, water, or water-based fluids may be used.

The flow diverter may comprise: a top plate arranged substantially parallel to the rear face of the heatsink, the top plate having an inner face facing towards the rear face of the heatsink and an outer face opposing the inner face, the top plate having a length extending between the inlet and outlet of the thermal module; a plurality of inner baffles for blocking flow of the cooling fluid, the inner baffles extending from the inner face of the top plate towards the rear face of the heatsink; a plurality of outer baffles for blocking flow of the cooling fluid, the inner baffles extending from the outer face of the top plate to an inner wall of the thermal module; and a plurality of through-slots in the top plate configured to allow the cooling fluid to flow between the inner and outer surfaces of the top plate, wherein inner baffles and outer baffles are arranged alternately along the length of the top plate.

The plurality of through-slots may comprise a first plurality of through-slots located in the top plate between inner and outer baffles, and a second plurality of through-slots located in the top plate between outer and inner baffles. The first plurality of through-slots may be arranged between the inner and outer baffles to enable flow of the cooling fluid towards the heatsink through the top plate, and the second plurality of through-slots are arranged between the outer and inner baffles to enable flow of the cooling fluid from the outer face of the top plate towards the heatsink, and wherein the first and second plurality of through-slots are arranged along the length of the top plate of the flow diverter so as to allow the cooling fluid to meander through the thermal module chamber alternately away from the heatsink through the second plurality of through-slots and towards the heatsink through the first plurality of through-slots.

Each of the first plurality of through-slots may comprise a plurality of rows of parallel slots. Each of the second plurality of through-slots may comprise a single through-slot arranged perpendicular to the first plurality of through-slots and extending over a portion of a height of the top plate.

The height of one or more of the inner and/or outer baffles may be less than the height of the top plate so as to permit at least a portion of the cooling fluid to flow over the top of or underneath the respective inner or outer baffle.

The heatsink rear face may comprises one or more heat exchange elements arranged to contact the cooling fluid in the thermal module chamber. The one or more heat exchange elements may comprise pins or fins projecting from the rear face of the heatsink into the thermal module chamber.

The power module cooling arrangement may comprise a second heatsink having a second plurality of power modules mounted and thermally coupled thereto, and a second thermal module, the second thermal module having an inlet for receiving cooling fluid, and an outlet for expelling cooling fluid and a chamber flooded with cooling fluid, wherein the second heatsink is mounted to the second thermal module and a rear face of the second heatsink is exposed to the chamber of the second thermal module so as to be in contact with the cooling fluid in the chamber of the second thermal module, the rear face of the second heatsink being opposed the front face of the second heatsink; and a flow diverter in the flow path of the cooling fluid between the inlet and outlet of the second thermal module.

The first and second thermal modules may be arranged substantially parallel to one another and separated by a gap. In some embodiments, the first and second modules may be arranged substantially parallel to one another without a gap therebetween. In embodiments having a gap between the first and second thermal modules, one or more components may be within the gap between the respective pair of thermal modules. The first and second thermal modules may be thermally coupled to the respective one or more components.

The first and second thermal modules may be supported and joined together at each end using respective support structures, and wherein the first and second thermal modules and respective support structures surround the one or more components.

The heatsink may be configured as a busbar for transferring power between the respective one or more of the plurality of power devices mounted thereto.

### LIST OF FIGURES

We will now describe the invention, by way of example only, and with reference to the following figures, in which:

FIG. 1 is an example circuit diagram for a power converter such as an inverter;

FIG. 2 shows an example arrangement of power switching devices mounted to a heatsink;

FIG. 3 shows a simplified illustration of a thermal module;

FIG. 4 shows the heatsink mounted to the thermal module;

FIG. 5 shows the rear face of the heatsink;

FIG. 6 shows an embodiment having a flow diverter in the flow path of the cooling fluid between the inlet and outlet;

FIGS. 7 to 10 show the flow diverter in isolation;

FIG. 11 shows an embodiment where the inner baffles extend only a portion along the height of the top plate;

FIGS. 12 and 13 show a preferred arrangement for one of the phases of a power converter;

FIGS. 14 and 15 show aspects of the cooling arrangement, and its use in cooling components of a power converter;

FIGS. 16 and 17 show an example power converter using the cooling arrangement as described, where FIG. 16 shows a cut-through view and FIG. 17 shows a projection view;

FIG. 18 shows a cut away view of an example power converter;

FIG. 19 shows an alternative arrangement of the DC capacitors; and

FIG. 20 shows an alternative arrangement of the DC capacitors and the thermal modules.

### DETAILED DESCRIPTION OF THE PREFERRED EMBODIMENTS

In brief, we will describe a power converter cooling arrangement in which a base has a top plate of a thermally conductive material, and a bottom plate and side walls define a chamber. An inlet and outlet are in fluid communication with the chamber, and the chamber is flooded with a cooling fluid that flows between the inlet and outlet. A PCB of a power converter is mounted to, and thermally coupled with, the top plate, where the PCB receives a plurality of power modules (that are used in the power conversion). Furthermore, the base comprises a plurality of fluid channels for flowing cooling fluid therethrough. Each of the fluid channels is arranged to coincide with a location of one or more components mounted to the PCB. Such an arrangement offers improved cooling of components within the power converter when compared to prior art solutions.

We also describe a power module cooling arrangement, where the power module is suitable for converting an input voltage into an output voltage. A plurality of power devices are mounted on and thermally coupled to a front face of a heatsink. The heatsink is mounted to a thermal module, which has a chamber flooded with a cooling fluid, and inlets and outlets in fluid communication with the chamber. The heatsink is mounted to the thermal module is such a way that a rear face of the heatsink (that is the face opposing the front face of the heatsink to which the power modules are mounted) is exposed to the chamber of the thermal module so as to be in contact with the cooling fluid in the chamber of the thermal module. The arrangement also comprises a flow diverter in the flow path of the cooling fluid between the inlet and outlet of the thermal module. The flow diverter is arranged to cause the cooling fluid to meander through the thermal module chamber, to focus the fluid, and to cause turbulence in the cooling fluid, all in support of thermal management efficiency. Such an arrangement offers improved cooling of the power modules when compared to prior art solutions.

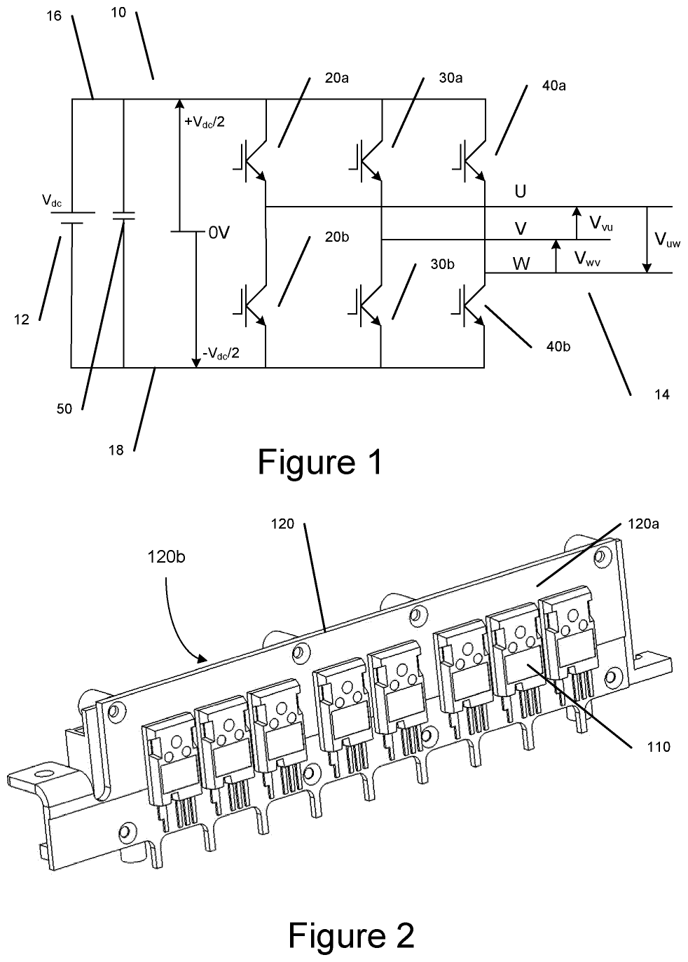

Power converters are generally known. One example may be found in U.S. Pat. No. 8,958,222, from which FIG. 1 is taken, and shows a simplified three phase power inverter 10 for converting a DC power supply 12 to an AC output 14 which may then be connected to a load (not shown). The inverter comprises three separate phases 20, 30, 40 (also referred to as phases U, V, W respectively). Each phase includes two switches in series: 20a, 20b in phase U; 30a, 30b in phase V; and 40a, 40b in phase W. Switches 20a, 30a and 40a are connected to the positive rail 16 (and may be referred to as the “upper” switches) and switches 20b, 30b and 40b are connected to the negative rail 18 (and may be referred to as the “lower” switches). In FIG. 1, each switch may be an IGBT (insulated gate bipolar transistor) and, for each IGBT, an associated anti-parallel diode may be used (not shown). However, any switches with fast switching capability may be used. A control system (such as a processor) (not shown) controls the switching of the switches 20a, 20b, 30a, 30b, 40a, 40b to control the AC output of the inverter 10. The power inverter also includes a DC bus capacitor 50, which provides a more stable DC voltage, limiting fluctuations as the inverter sporadically demands heavy current. Whilst the DC bus capacitor is represented as a single capacitor, the DC bus capacitor in practice is made up of one or more capacitors. A sinusoidal output current can be created at AC output 14 by a combination of switching states of the six switches.

Due to the currents involved in power conversion, particularly high power conversion for inverters used to power electric motors, heat is generated within the circuit components and the circuit connections and PCBs.

Prior art solutions have addressed this problem by submerging the entire circuit in a cooling fluid, for example in a chamber that has an inlet and outlet in fluid communication with the chamber, and where the cooling fluid flows through the chamber to extract heat from the components, circuits and PCB. However, a problem with this arrangement is that, since the oil is in contact with the components and PCB, there is a burden on the designers and manufacturers to qualify the components and PCB for use in submerged cooling fluid, such as a dielectric oil.

We are attempting to address this issue by cooling different parts of the system using a contained cooling fluid solution. That is, the cooling fluid is contained in defined areas, so the PCB and components are not submerged in the cooling fluid, which reduces the qualification burden on the components being used in the system.

We will discuss two main areas:
(i) Cooling of the power devices and DC capacitors
(ii) Cooling of other bulky components and PCB

### Cooling Power Devices and DC Capacitors

Referring to the upper 20a, 30a, 40a and lower 20b, 30b, 40b switches of the converter 10, each switch comprises a plurality of discrete power switching devices mounted to a heatsink. The plurality of power switching devices operate together to provide the functionality of a larger switch.

FIG. 2 shows an example arrangement of power switching devices 110 mounted to a heatsink 120. The power devices 110 are mechanically and thermally connected to the heatsink 120 so that they are supported on the heatsink 120 and that heat from the power devices 110 may flow into the heatsink 120. Furthermore, in some embodiments, the heatsink 120 may also act as a busbar, that is current may flow between the power devices 110 and the heatsink 120 and also between the heatsink 120 and any PCB or other components that may be electrically connected to the heatsink 120. For ease of reference, the face of the heatsink 120 to which the power devices 110 are mounted will be referred to as the front face 120a of the heatsink 120. The opposite face to the front face 120a of the heatsink 120 will be referred to as the rear face 120b of the heatsink 120.

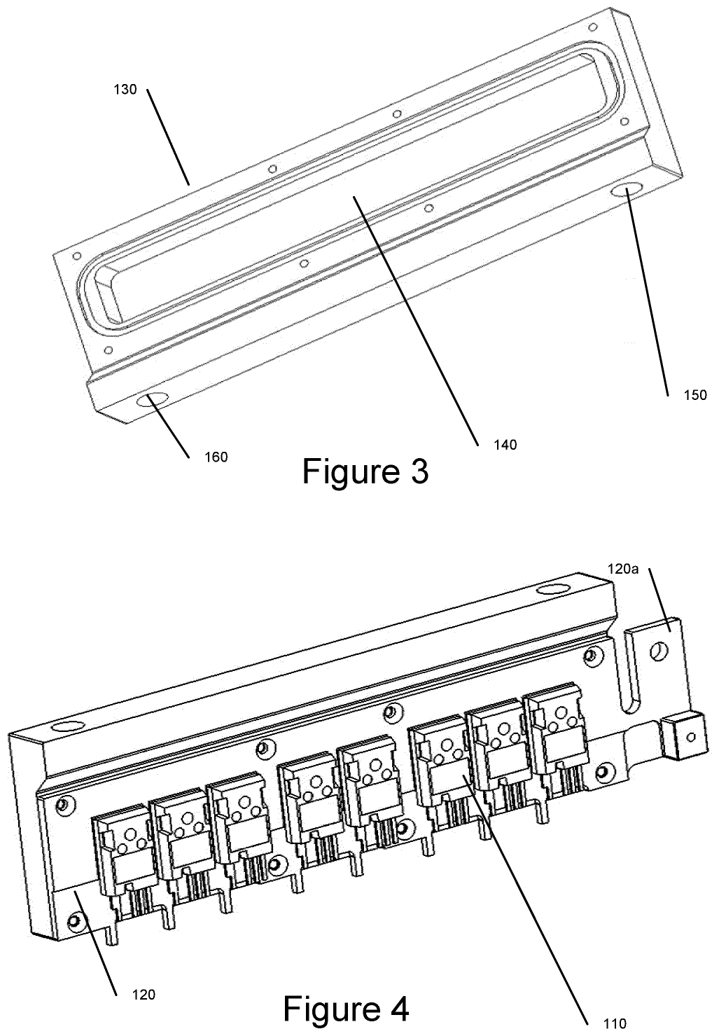

FIG. 3 shows a simplified illustration of a thermal module 130. To provide the cooling for the heatsink 120 and power devices 110, the heatsink is mounted to the thermal module 130. The thermal module 130 comprises a body having a chamber 140 in which cooling fluid may flow. An inlet 150 and outlet 160 in fluid communication with the chamber 140 enable the cooling fluid to flow into and out of the chamber 140.

FIG. 4 shows the heatsink 120 mounted to the thermal module 130. The heatsink 120 is mounted to the heatsink so as to create a fluid-tight seal with the chamber 140. The heatsink 120 is mounted such that the rear face 120b of the heatsink 120 is exposed to the chamber 140, and thus in contact with the cooling fluid flowing through the chamber 140.

Since the heatsink 120 may also function as a busbar to conduct current between devices, the thermal module 130 is preferably made from a non-conductive material such as a polymer material, exemplified by (but not limited to) high temperature nylon (HTN), polyphenylene sulphide, polyetherimide, polysulphones, polythalamide and glass filled versions of these.

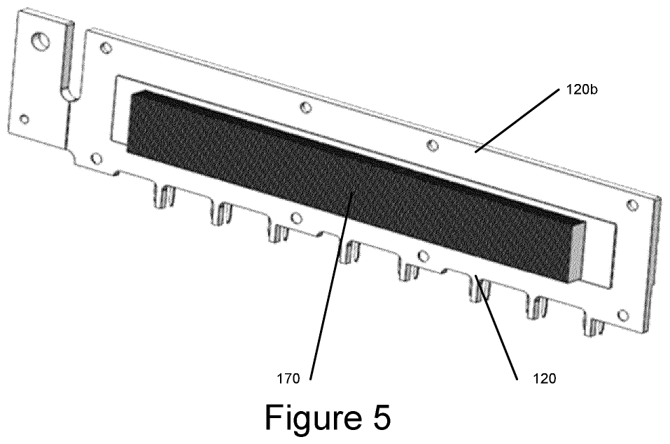

FIG. 5 shows the rear face 120b of the heatsink 120. In some embodiments, the rear face 120b of the heatsink 120 may be provided with heat exchange elements 170 to provide an increase in thermal transfer between the heatsink 120 and the cooling fluid that is in contact with the heatsink 120 in the chamber 140. These heat exchange elements 170 may take the form of pins or fins or other similar features extending from the rear face 120b of the heatsink 120 and into the chamber 140. Such an arrangement provides an increased surface area in contact with the cooling fluid in the chamber 140.

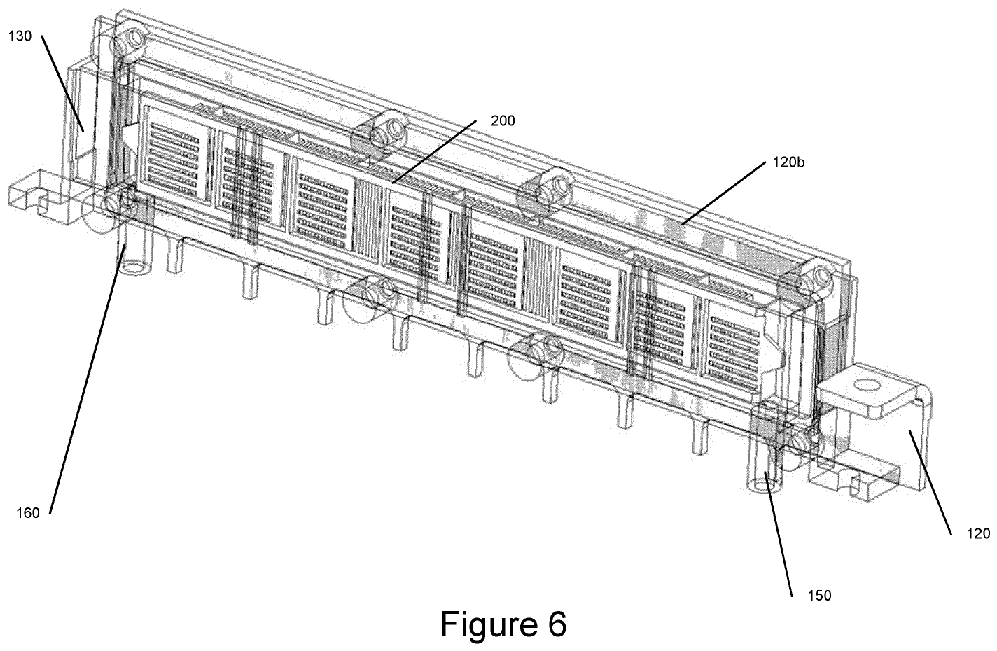

FIG. 6 shows an embodiment having a flow diverter 200 in the flow path of the cooling fluid between the inlet 150 and outlet 160. The flow diverter is arranged to cause the cooling fluid to meander through the thermal module 130, which improves the heat transfer between the heatsink 120 and the cooling fluid. Furthermore, the flow diverter 200 may cause turbulence within the cooling fluid, and may also provide a jetting function, focussing portions of the cooling fluid onto the back of the heatsink.

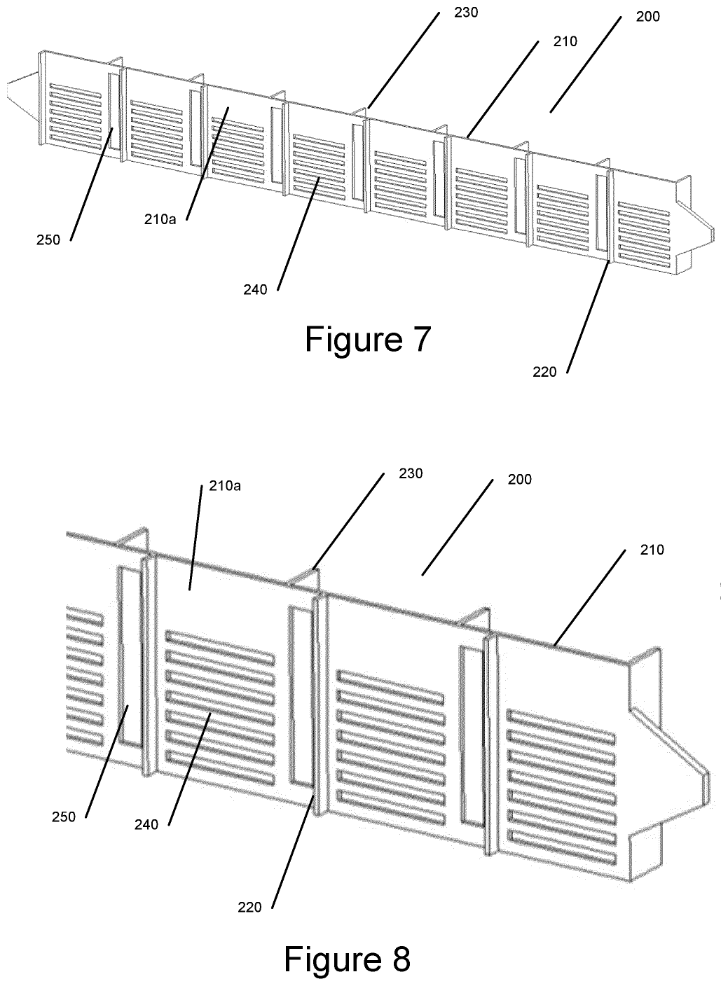

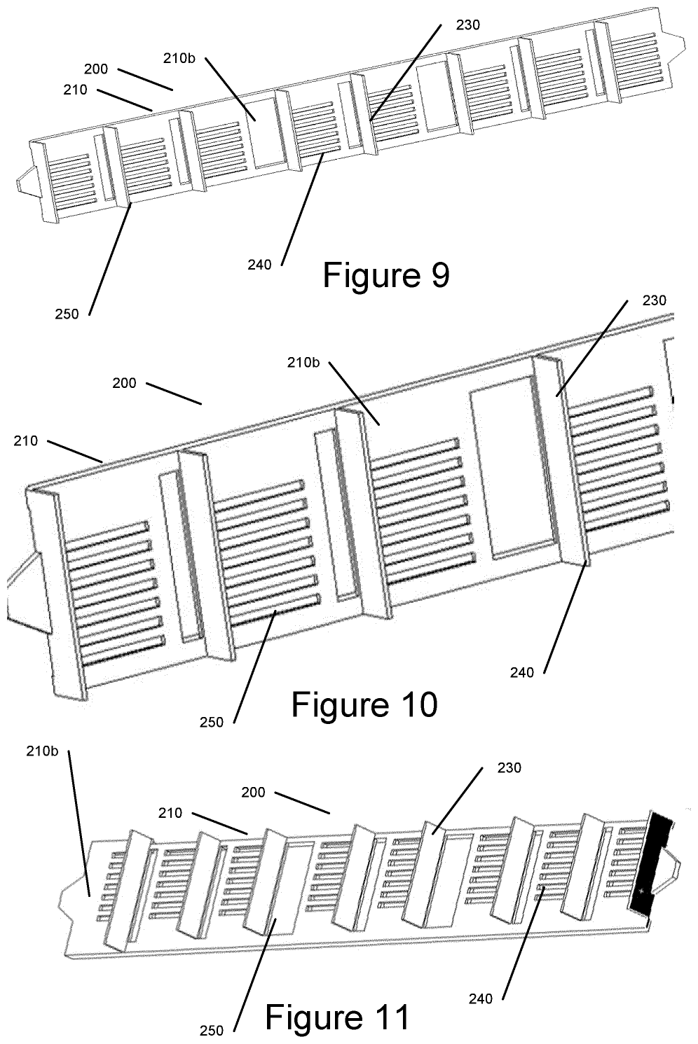

FIGS. 7 to 9 show the flow diverter 200 in isolation for the sake of clarity. The flow diverter 200 comprises a top plate 210 arranged substantially parallel to the rear face 120b of the heatsink 120. The top plate 210 has an inner face 210b facing towards the rear face 120b of the heatsink 120 and an outer face 210a opposing the inner face 210b. The top plate 210 has a length that extends along at least a portion of the length of the chamber 140. In embodiments, the length of the top plate 210 may extend between the inlet 150 and outlet 160 of the thermal module 130.

The flow diverter 200 comprises a plurality of inner baffles 230 for blocking flow of the cooling fluid. The inner baffles 230 extends from the inner face 210b of the top plate 210 towards the rear face 120b of the heatsink 120. The flow diverter 200 also comprises a plurality of outer baffles 220 for blocking flow of the cooling fluid. The outer baffles 220 extend from the outer face 210a of the top plate 210 to an inner wall of the chamber 140 of the thermal module 130.

In some embodiments, the outer 220 and/or inner 230 baffles extend along the height of the top plate 210, which blocks the flow of the cooling fluid between the inlet 150 and outlet 160.

In order to force the cooling fluid to meander through the chamber 140 of the thermal module 130, the flow diverter 200 is provided with a plurality of through-slots 240, 250 in the top plate 210 that are arranged to enable the cooling fluid to flow between the inner 210b and outer 210a surfaces of the top plate 210.

The inner 230 baffles and outer 220 baffles are arranged alternately along the length of the top plate 210.

There are two groupings of the plurality of through-slots 240, 250. The first plurality of through-slots 240 are located in the top plate 210 between inner 230 and outer 220 baffles. In the preferred embodiments, the first plurality of through-slots 240 are arranged between the inner 230 and outer 220 baffles to enable flow of the cooling fluid towards the heatsink 120 through the top plate 200. As shown in the figures, the first plurality of through-slots 230 may be in the form of a plurality of horizontal slots, although other configurations would be apparent to the skilled reader. Furthermore, whilst these have been described as slots, the holes need not be limited to a slot configuration; other hole shapes me be used instead of slots.

The second grouping of through-slots 250 are located in the top plate 210 between outer 220 and inner 230 baffles. The second plurality of through-slots 250 are arranged between the outer 220 and inner 230 baffles to enable flow of the cooling fluid from the outer face 210a of the top plate 210 towards the heatsink 120. As shown in the figures, each of the second plurality of through-slots comprise a vertical slot, although other configuration or arrangements would be apparent to the skilled reader. Similarly, whilst these have been described as slots, the holes need not be limited to a slot configuration; other hole shapes may be used instead of slots.

The first 240 and second 250 plurality of through-slots, together with the inner 230 and outer 220 baffles, are arranged along the length of the top plate 219 of the flow diverter 200 so as to allow the cooling fluid to meander through the chamber 140 alternately away from the heatsink 120 through the second plurality 250 of through-slots and towards the heatsink 120 through the first plurality of through-slots 240.

As discussed above, in some embodiments, the outer 220 and/or inner 230 baffles extend along the height of the top plate 210, which blocks the flow of the cooling fluid between the inlet 150 and outlet 160, which forces all of the cooling fluid to meander away from and towards the heatsink 120.

FIG. 11 shows an embodiment where the inner 230 baffles extend only a portion along the height of the top plate 210.

In these embodiments, one or more of the outer 220 and/or inner 230 baffles extend only a portion along the height of the top plate 210, which partially blocks the flow of the cooling fluid between the inlet 150 and outlet 160, and enables a portion of the cooling fluid from one section to bleed over the baffles into the adjacent section without having to meander away from the heatsink 120. It has been found that this arrangement provides improved cooling performance over embodiments where the outer 220 and inner 230 extend the height of the flow diverter 200, since cooler cooling fluid from a previous section may bleed through into the next section. This is particularly useful in this arrangement where each section is fed sequentially from the previous section. As such, without the bleed paths, the power devices 110 associated with the final section receives the hottest cooling fluid (due to heating from the previous sections). By implementing the bleed paths, cooler fluid is able to reach the hottest power devices 110 and thus reduce thermal stresses on those components. Furthermore, it has been found that such an arrangement reduces the overall pressure drop of the cooling fluid between the inlet 150 and output 160.

Preferably at least the first baffle in the flow path between the inlet 150 and outlet 160 has a reduced height. In some embodiments some or all of the rest of the baffles also have a reduced height.

We have described embodiments where a heatsink 120 is mounted to a thermal module 130.

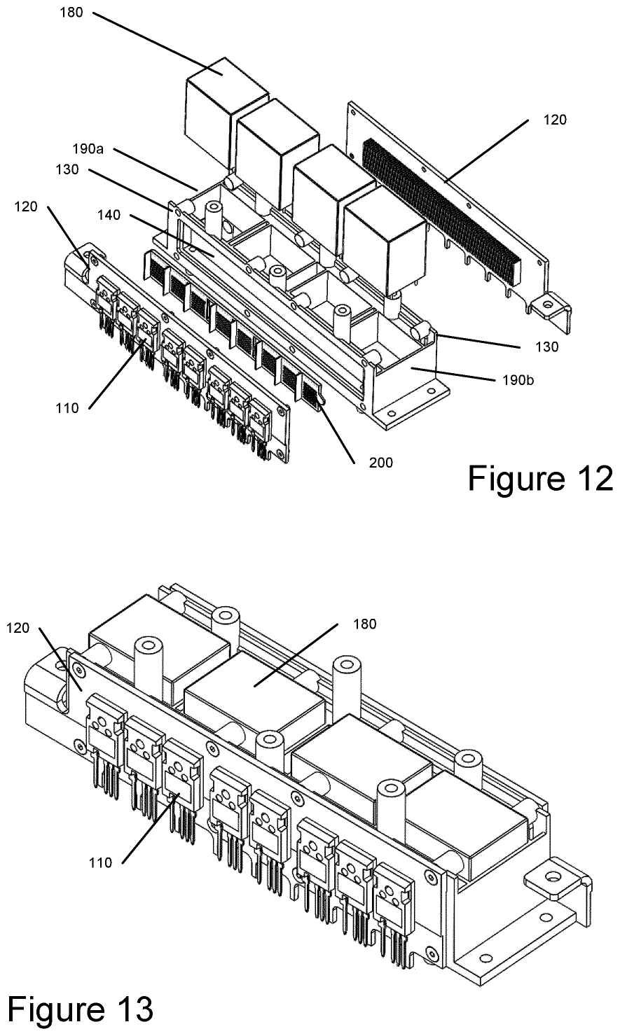

FIGS. 12 and 13 show a preferred arrangement for one of the phases of a power converter.

In some embodiments, the number of power devices 110 to implement the switches in one of the phases are split over two heatsinks 120. In such an arrangement, each heatsink 120 is mounted to a respective thermal module 130, each module 130 comprising a thermal chamber 140. In this arrangement, the thermal modules 130 can be arranged with a gap 190a between them. With a suitably-sized gap 190a it is possible to sandwich other components between the thermal modules 130. In the example shown, the DC capacitors 180 are located in the gap 190a and the thermal modules 130 are spaced apart so as to fit the DC capacitors 180 therebetween and also for the modules 130 to be in contact with the DC capacitors 180. Such an arrangement enables the thermal modules 130 to be in thermal contact with the DC capacitors 180 so as to remove heat from the DC capacitors 180. This arrangement also provides a compact configuration for the phase, minimising the space required to implement the switches with cooling.

In some embodiments, the pair of thermal modules 130 are supported and joined together at each end using support structures 190b. In such an arrangement, the pair of thermal modules 130 and support structures 190b surround the DC capacitors 180. In some embodiments, the support structures 190b are solid wall portions extending from each of the thermal modules 130 so as to be a single piece with the thermal modules 130. In other embodiments, additional flow channels in the walls of the support structures 190b may be provided between the thermal modules 130. The flow channels may be in fluid communication with either or both of the chambers 140 to provide additional flow between the chambers 140. In any of the above embodiments, the thermal module 130 with support structures 190b may be formed of a single piece or multiple pieces joined together.

In a multi-phase converter, each phase may be arranged in this way to provide a modular solution.

### Cooling PCB and Other Components

We will now describe the cooling of PCB and other components used in a power converter.

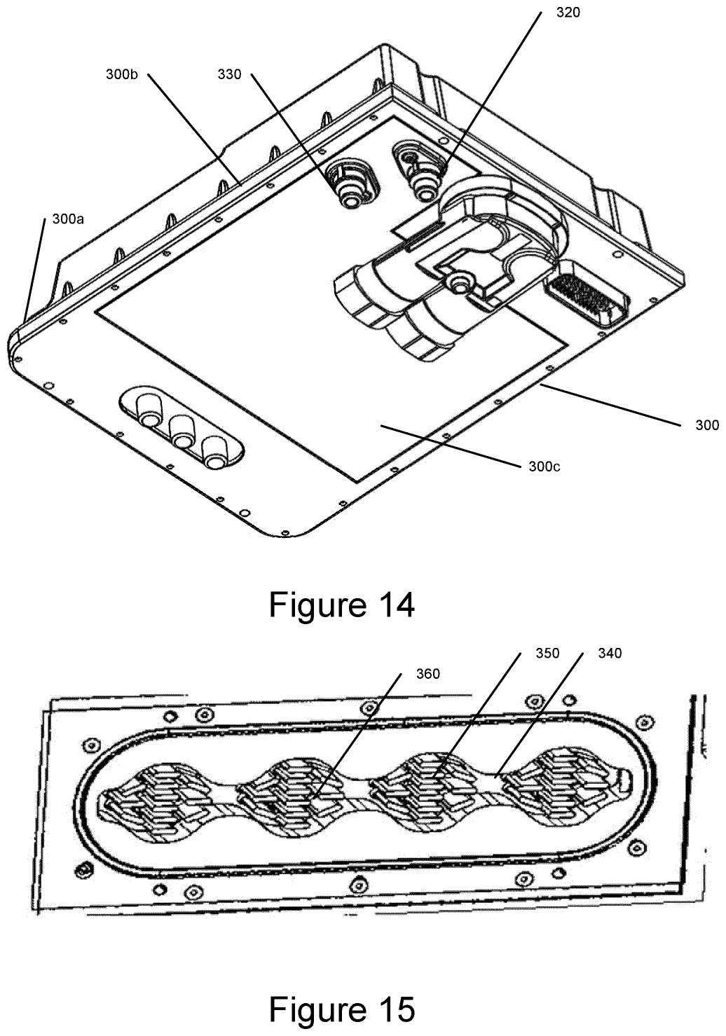

FIGS. 14 to 17 show aspects of the cooling arrangement, and its use in cooling components of a power converter. Whilst some of these figures show the PCB cooling arrangement in combination with the power module cooling arrangement (as discussed above), it is to be understood that the PCB cooling arrangement may be used instead of or as well as the power module cooling arrangement.

A base 300 is provided with a top plate 300a, side walls 300b and a bottom plate 300c. The PCB 370 (carrying various components, copper tracks and the like) is mounted to an outer surface of the top plate 300a. The PCB 370 may be mechanically connected or bonded to the top plate 300a, and also thermally coupled to the top plate 300a. The top plate 300a, side walls 300b and bottom plate 300c define a chamber 310 that is in fluid communication with an inlet 320 and outlet 330. The chamber 310 is flooded with a cooling fluid that flows between the inlet 320 and outlet 330.

The base 300 comprises a plurality of fluid channels 340 for flowing cooling fluid therethrough. Each of the fluid channels 340 is arranged to coincide with a location of one or more components mounted to the PCB, or where other areas of the top plate 300a where cooling is required or desired.

Preferably at least the top plate 300a is made from a thermally conductive material in order to facilitate cooling of the PCB 370 and other components.

In some embodiments, one or more of the fluid channels 340 comprise one or more portions 350 having a greater width than other portions 340 of the fluid channels. This advantageously provides an area of greater cooling, since the surface area of the underside of the top plate 300a in contact with the cooling fluid in those regions is increased.

To provide even greater cooling, one or more cooling features or heat exchange elements 360 may protrude from an inner surface of the top plate 300a into the one or more wider portions 350 of the fluid channels 340 and contact with the cooling fluid. Again, the heat exchange elements 360 increase the contact surface area of the top plate 300a with the cooling fluid, which increases the amount of heat that is able to be transferred from the top plate 300a into the cooling fluid. These heat exchange elements 360 may also be provided in the narrower portions of the fluid channel(s) 340. The one or more cooling features 360 may comprise pins or fins or other known heat exchanging elements.

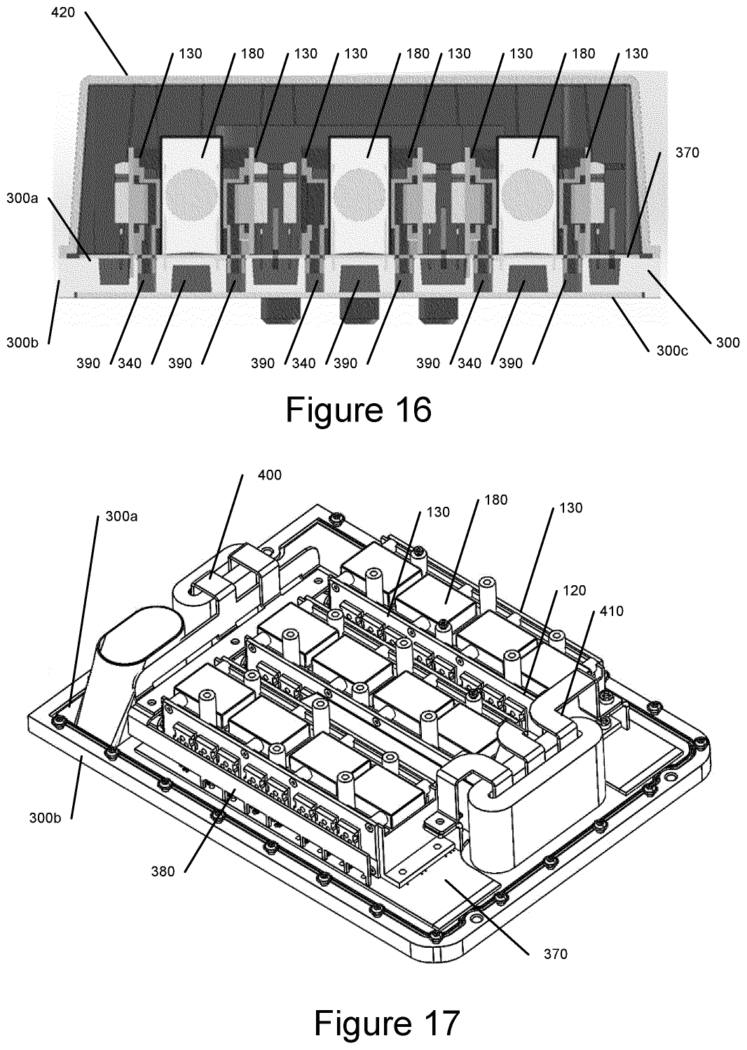

FIGS. 16 and 17 show example power converter using the cooling arrangement as described, where FIG. 16 shows a cut-through view and FIG. 17 shows a projection view. Again, whilst this figure shows both the PCB cooling and power module cooling, both cooling aspects need not be used together. However, using both cooling aspects together is preferred since the cooling performance is greatly improved.

Focusing first on the PCB cooling, and as discussed above, the base 300 has as inlet 320 and outlet 330 in fluid communication with the chamber 310, and the chamber is in fluid communication with the one or more fluid channels 340. The fluid channels 340 are shown arranged underneath the position of the DC capacitors 180. In the preferred embodiments, the widened portions 350 of the fluid channels 340 are located to coincide with the location of the DC capacitors 180. This provides improved cooling for the PCB in those regions, and also for the DC capacitors 180 themselves.

The fluid channels 340 may also coincide with areas of the PCB 370 comprising other components or even features or tracks within the PCB 370 that are configured to improve heat transfer into the cooling fluid. For example, large copper tracks within the PCB 370 layers, for carrying larger currents, may be positioned over or adjacent the fluid channels 340 for improved heat transfer. Furthermore, other components or features of the power converter, such as busbars 380 that carry large currents may also be arranged on the PCB 370 in such a way as to receive additional cooling, or may be arranged in such a way that heat is extracted via the top plate 300a of the base 300.

For embodiments where the thermal modules 130 are also cooled, as shown in FIGS. 16 and 17, additional fluid channels 390 are provided in order to supply cooling fluid to the chambers 140 of the thermal modules 130 via the inlets 150 and outlets 160. These additional fluid channels 390 are in fluid communication with the chamber 310 of the base 300.

By using such an arrangement, components are separated from the cooling fluid, whilst still being cooled by the cooling fluid. As such, the cooling fluid is contained in defined areas, so the PCB and components are not submerged in the cooling fluid, which reduces the qualification burden on the components being used in the system.

The power converter shown also comprises one or more inputs 400 for receiving one or more voltage inputs, and one or more outputs 410 for outputting one or more output voltages. In the preferred embodiments, the power converter is an inverter, which receives a DC input voltage and outputs one or more AC output phase voltages, preferably three phase AC output voltages. DC and/or AC chokes may be provided in order to reduce EMI. These one or more AC output phase voltages may be suitable for powering loads such as motors or heaters or other known loads.

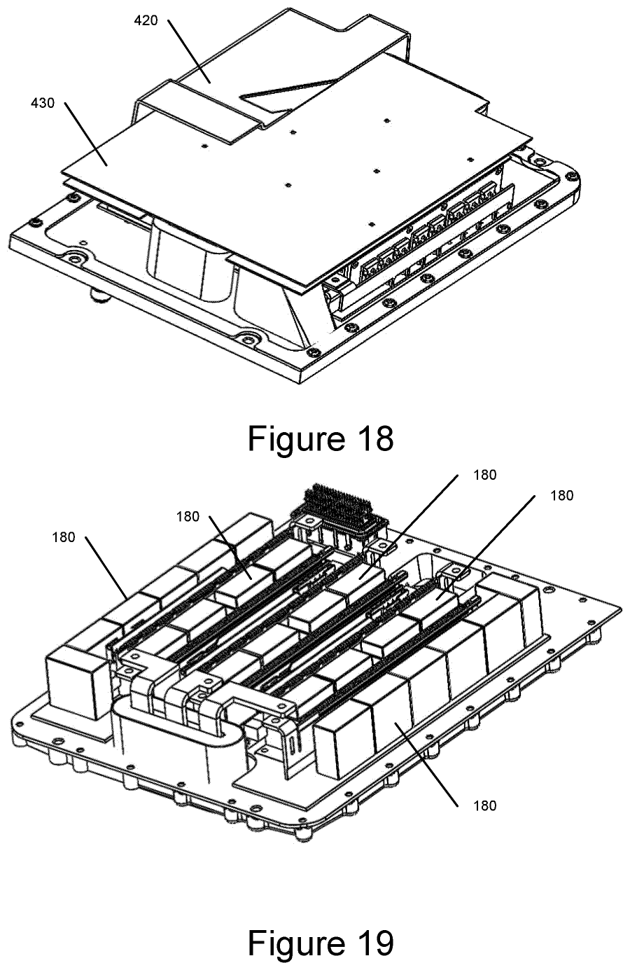

FIG. 18 shows a cut away view of an example power converter.

The power converter shown may also comprise a control PCB 430, which may, for example, be arranged above the power components such as the power devices 110 and thermal modules 130. The converter may also be covered in a housing 420, to protect the components from the external environment, which may be an environment that is harsh to the devices.

FIG. 19 shows an alternative arrangement of the DC capacitors 180. In this arrangement, there are five rows of smaller capacitors 180 as opposed to three rows as in the previous embodiments. This may reduce the overall enclosure height and also reduce phase connection loss and AC loop inductance, since the capacitors are more distributed so act more in parallel, and the connection between heatsinks for each phase is shorter. In such an arrangement as shown, the three middle rows of capacitors 180 may be cooled via the thermal modules 130 (if present) and the base top plate 300a, and the outer two rows of capacitors 180 are cooled via the base top plate 300a.

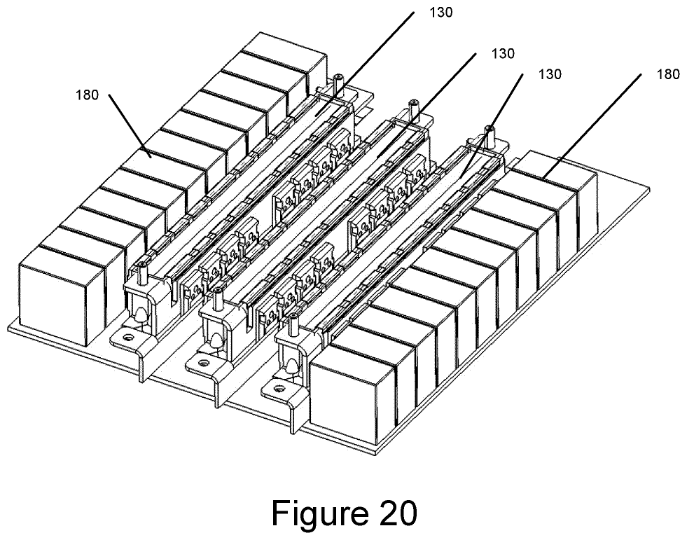

FIG. 20 shows a further alternative arrangement. In this arrangement, each pair of thermal modules 130 are arranged back-to-back. That is, without a gap between the thermal modules 130 that would allow the placement of other components for cooling. The DC capacitors 180 are arranged, for example, at the outer sides of the PCB. This is one example arrangement of the DC capacitors 180, although other arrangements are possible. For example, banks of DC capacitors 180 may be arranged between adjacent thermal modules 130 as well as or instead of additional banks at the outer edges. Modifications are also made to the base 300 in order to take into account the placement of the DC capacitors 180. For example, the fluid channels 340 and widened portions 350 of the fluid channels are arranged beneath the location of the DC capacitors. Such arrangements offers a reduced length of the phase tracks on the PCB (these may run below the thermal chambers); the tracks may be longer (so have greater resistance, which gives greater loss through heat) in embodiments where the DC capacitors are between the thermal modules. In the alternative implementations where the capacitors are away from the thermal modules, the DC capacitors are not cooled-via the thermal modules, and we have found that the cold plate function, that the base top plate provides, is adequate to cool the DC capacitors.

In any of the embodiments, the cooling fluid may be a dielectric cooling fluid having suitable characteristics depending on the use and the arrangement of the components and thermal modules. Preferably the dielectric cooling fluid may have a suitable dielectric strength for embodiments where the fluid is not electrically isolated from the heatsink (for example when the heatsink is used as a busbar). For embodiments where the heatsink is not used as a busbar, and instead there is electrical isolation between the cooling fluid and the power devices or other components, a non-dielectric cooling fluid may be used, such as water, or water-based cooling fluids.

As discussed above, the present invention may provide at least the following advantages:
Contained fluid common circuit (a range of dirty and aggressive oils can be used without the issues of touching the electric components or PCBs). Alternatively, when electrical isolation is introduced between the busbar and heatsink, water, or water-based fluids may be used.)
Cooling the power devices is provided by jets and turbulence and the heatsinks may also be busbars
Low AC loop inductance due to the position of the DC capacitance and the power devices
Low PCB output capacitance due to the power PCB layers
Cooling the capacitors using the inside of the thermal chamber (when this embodiment is used) and through the power board PCB from the cold plate (when this embodiment is used)
Cooling the power PCB using a cold plate and limiting the amount of high current that the power board PCB carries by the use of short planes and bus bars

No doubt many other effective alternatives will occur to the skilled person. It will be understood that the invention is not limited to the described embodiments and encompasses modifications apparent to those skilled in the art lying within the scope of the claims appended hereto.

1. A power converter cooling arrangement, the power converter for converting an input voltage into an output voltage,
the power converter comprising:
an input for receiving an input voltage, and an output for outputting an output voltage;
a plurality of power modules connected between the input and output, each module comprising a plurality of power devices mounted on and thermally coupled to a front face of a heatsink, the power module for converting the input voltage into an output voltage;
a plurality of capacitors connected to the input;
wherein the plurality of power modules and the plurality of capacitors are mounted to a PCB,
the cooling arrangement comprising:
a base having a top plate of a thermally conductive material, a bottom plate and side walls defining a chamber, and an inlet and outlet in fluid communication with the chamber, the chamber being flooded with a cooling fluid that flows between the inlet and outlet, wherein the PCB is mounted to, and thermal coupled with, an outer surface of the top plate of the base, and
wherein the base comprises a plurality of fluid channels for flowing cooling fluid therethrough, each of the fluid channels being arranged to coincide with a location of one or more components mounted to the PCB.

2. A power converter cooling arrangement according to claim 1, wherein one or more of the fluid channels comprise one or more portions having a greater width than other portions of the fluid channels.

3. A power converter cooling arrangement according to claim 2, wherein one or more cooling features protrude from an inner surface of the top plate into the one or more wider portions of the fluid channels and in contact with the cooling fluid.

4. (canceled)

5. A power converter cooling arrangement according to claim 1, wherein one or more of the capacitors and/or one or more heatsinks and/or one or more features of one or more of the power devices are located to coincide with one or more of the fluid channels of the base.

6. (canceled)

7. A power converter cooling arrangement according to claim 1, wherein the heatsink of each of the plurality of power modules is mounted to a thermal module, the thermal module having an inlet for receiving cooling fluid, and an outlet for expelling cooling fluid and a chamber flooded with cooling fluid, the inlet and outlet of the thermal module being in fluid communication with the chamber of the base.

8. A power converter cooling arrangement according to claim 7, wherein the thermal module inlet and outlet extend through the PCB into the base.

9. A power converter cooling arrangement according to claim 7, wherein a rear face of the heatsink is exposed to the chamber of the thermal module so as to be in contact with the cooling fluid in the chamber of the thermal module, the rear face of the heatsink being opposed the front face of the heatsink.

10. A power converter cooling arrangement according to claim 7, wherein the heatsink rear face comprises one or more heat exchange elements arranged to contact the cooling fluid in the thermal module chamber.

11-12. (canceled)

13. A power converter cooling arrangement according to claim 8, comprising a flow diverter in the flow path of the cooling fluid between the inlet and outlet of the thermal module, the flow diverter being arranged to cause the cooling fluid to meander through the thermal module chamber.

14. A power converter cooling arrangement according to claim 13, wherein the flow diverter comprises:
a top plate arranged substantially parallel to the rear face of the heatsink, the top plate having an inner face facing towards the rear face of the heatsink and an outer face opposing the inner face, the top plate having a length extending between the inlet and outlet of the thermal module;
a plurality of inner baffles for blocking flow of the cooling fluid, the inner baffles extending from the inner face of the top plate towards the rear face of the heatsink;
a plurality of outer baffles for blocking flow of the cooling fluid, the outer baffles extending from the outer face of the top plate to an inner wall of the thermal module; and
a plurality of through-slots in the top plate configured to allow the cooling fluid to flow between the inner and outer surfaces of the top plate,
wherein inner baffles and outer baffles are arranged alternately along the length of the top plate.

15. A power converter cooling arrangement according to claim 14, wherein the plurality of through-slots comprises a first plurality of through-slots located in the top plate between inner and outer baffles, and a second plurality of through-slots located in the top plate between outer and inner baffles.

16. A power converter cooling arrangement according to claim 15, wherein the first plurality of through-slots are arranged between the inner and outer baffles to enable flow of the cooling fluid towards the heatsink through the top plate, and the second plurality of through-slots are arranged between the outer and inner baffles to enable flow of the cooling fluid from the outer face of the top plate towards the heatsink, and wherein the first and second plurality of through-slots are arranged along the length of the top plate of the flow diverter so as to allow the cooling fluid to meander through the thermal module chamber alternately away from the heatsink through the second plurality of through-slots and towards the heatsink through the first plurality of through-slots.

17. A power converter cooling arrangement according to claim 15, wherein each of the first plurality of through-slots comprise a plurality of rows of parallel slots.

18. A power converter cooling arrangement according to claim 15, wherein each of the second plurality of through-slots comprise a single through-slot arranged perpendicular to the first plurality of through-slots and extending over a portion of a height of the top plate.

19. A power converter cooling arrangement according to claim 14, wherein the height of one or more of the inner and/or outer baffles is less than the height of the top plate so as to permit at least a portion of the cooling fluid to flow over the top or underneath the respective inner or outer baffle.

20. A power converter cooling arrangement according to claim 7, wherein the plurality of power modules are arranged in a plurality of pairs of modules.

21. A power converter cooling arrangement according to claim 20, wherein, for each pair of power modules, the respective pair of thermal modules are arranged substantially parallel to one another and separated by a gap.

22. A power converter cooling arrangement according to claim 21, wherein the one or more of the capacitors are located within the gap between the respective pair of thermal modules.

23. A power converter cooling arrangement according to claim 22, wherein the respective pair of thermal modules are thermally coupled to the respective one or more capacitors.

24. A power converter cooling arrangement according to claim 22, wherein the respective pair of thermal modules are supported and joined together at each end using respective support structures, and wherein the respective pair of thermal modules and respective support structures surround the one or more capacitors.

25. A power converter cooling arrangement according to claim 1, wherein, for one or more of the power modules, a respective heatsink is configured as a busbar for transferring power between the respective one or more of the plurality of power devices mounted thereto.

26-32. (canceled)

33. A power module cooling arrangement, the power module for converting an input voltage into an output voltage, comprising:
a plurality of power devices mounted on and thermally coupled to a front face of a heatsink;
a thermal module having an inlet for receiving cooling fluid, and an outlet for expelling cooling fluid and a chamber flooded with cooling fluid, wherein the heatsink is mounted to the thermal module and a rear face of the heatsink is exposed to the chamber of the thermal module so as to be in contact with the cooling fluid in the chamber of the thermal module, the rear face of the heatsink being opposed the front face of the heatsink; and
a flow diverter in the flow path of the cooling fluid between the inlet and outlet of the thermal module,
wherein the flow diverter is arranged to cause the cooling fluid to meander through the thermal module chamber.

34. A power module cooling arrangement according to claim 33, wherein the flow diverter comprises:
a top plate arranged substantially parallel to the rear face of the heatsink, the top plate having an inner face facing towards the rear face of the heatsink and an outer face opposing the inner face, the top plate having a length extending between the inlet and outlet of the thermal module;
a plurality of inner baffles for blocking flow of the cooling fluid, the inner baffles extending from the inner face of the top plate towards the rear face of the heatsink;
a plurality of outer baffles for blocking flow of the cooling fluid, the inner baffles extending from the outer face of the top plate to an inner wall of the thermal module; and
a plurality of through-slots in the top plate configured to allow the cooling fluid to flow between the inner and outer surfaces of the top plate,
wherein inner baffles and outer baffles are arranged alternately along the length of the top plate.

35. A power module cooling arrangement according to claim 34, wherein the plurality of through-slots comprises a first plurality of through-slots located in the top plate between inner and outer baffles, and a second plurality of through-slots located in the top plate between outer and inner baffles.

36. A power module cooling arrangement according to claim 35, wherein the first plurality of through-slots are arranged between the inner and outer baffles to enable flow of the cooling fluid towards the heatsink through the top plate, and the second plurality of through-slots are arranged between the outer and inner baffles to enable flow of the cooling fluid from the outer face of the top plate towards the heatsink, and wherein the first and second plurality of through-slots are arranged along the length of the top plate of the flow diverter so as to allow the cooling fluid to meander through the thermal module chamber alternately away from the heatsink through the second plurality of through-slots and towards the heatsink through the first plurality of through-slots.

37. A power module cooling arrangement according to claim 35, wherein each of the first plurality of through-slots comprise a plurality of rows of parallel slots.

38. A power module cooling arrangement according to claim 35, wherein each of the second plurality of through-slots comprise a single through-slot arranged perpendicular to the first plurality of through-slots and extending over a portion of a height of the top plate.

39. A power module cooling arrangement according to claim 34, wherein the height of one or more of the inner and/or outer baffles is less than the height of the top plate so as to permit at least a portion of the cooling fluid to flow over the top of or underneath the respective inner or outer baffle.

40. A power module cooling arrangement according to claim 33, wherein the heatsink rear face comprises one or more heat exchange elements arranged to contact the cooling fluid in the thermal module chamber.

41-48. (canceled)
